(19) United States
(12) Patent Application Publication
(10) Pub. No.: US 2026/0114306 A1
(43) Pub. Date: Apr. 23, 2026

(54) SEMICONDUCTOR DEVICE

(71) Applicant: SHINKO ELECTRIC INDUSTRIES CO., LTD., Nagano-shi (JP)

(72) Inventor: Shinichiro Sekijima, Nagano (JP)

(21) Appl. No.: 19/362,561

(22) Filed: Oct. 20, 2025

(30) Foreign Application Priority Data
Oct. 21, 2024 (JP) 2024-184963

(51) Int. Cl. H01L 23/498

(52) U.S. Cl. CPC H10W 70/65; H10W 90/701

(57) ABSTRACT

A semiconductor device includes a first wiring substrate, an electronic component, a second wiring substrate, and a plurality of connection members. The second wiring substrate is laminated on the first wiring substrate by sandwiching the electronic component. The plurality of connection members connect the first wiring substrate and the second wiring substrate. Each of the plurality of connection members includes a pair of cores that are adjacent in a lamination direction, and a conductor film. At connection members that are arrayed in at least an innermost row or an outermost row, one core of the pair of cores that is closer to the second wiring substrate is arranged so as to be offset in a direction closer to the electronic component or in a direction away from the electronic component with respect to another of the pair of cores that is closer to the first wiring substrate.

### CROSS-REFERENCE TO RELATED APPLICATION

This application is based upon and claims the benefit of priority of the prior Japanese Patent Application No. 2024-184963, filed on October 21, 2024, the entire contents of which are incorporated herein by reference.

### FIELD

The present invention relates a semiconductor device.

### BACKGROUND

In recent years, in order to implement a high-density component mounting technique, a semiconductor device in which, for example, an electronic component, such as a semiconductor chip, is built in an interior portion of a substrate has been drawing attention. This type of semiconductor device includes, for example, two wiring substrates, and is constituted such that an electronic component, such as a semiconductor chip, is mounted on one of the wiring substrates, and is sandwiched by the other of the wiring substrates.

The two wiring substrates are connected by connection members. Specifically, a conductor ball that has been mounted on the other of the wiring substrates is arranged on a conductor ball that has been mounted on the one of the wiring substrates, and the other wiring substrate is laminated on the one wiring substrate. Each of the conductor balls is formed such that a spherical shaped core is covered by a conductor film, such as solder. Then, the conductor films that cover the two conductor balls mounted on the two laminated wiring substrates are integrated by being melted by heat and a pressure. As a result of this, the two wiring substrates are connected by the connection members each of which includes a pair of cores that are adjacent in a lamination direction of the two wiring substrates and the conductor film that cover the pair of cores.

Patent Document 1: Japanese Laid-open Patent Publication No. 2004-342959

Incidentally, when the conductor films that cover the two conductor balls that have been mounted on the two respective wiring substrates are integrated by being melted by heat and a pressure, the two conductor balls are pressurized by the two wiring substrates in the vertical direction. At this time, a contact between the two conductor balls to be pressurized is a point contact, so that the two conductor balls become slippery. As a result of this, there is a problem in that the conductor ball disposed on an upper side between the two conductor balls slides down from the conductor ball disposed on a lower side, and a positional shift accordingly occurs between the two wiring substrates that pressurize the two conductor balls.

### SUMMARY

According to an aspect of an embodiment, a semiconductor device includes a first wiring substrate; an electronic component that is provided on the first wiring substrate; a second wiring substrate that is laminated on the first wiring substrate by sandwiching the electronic component; and a plurality of connection members that are arrayed around the electronic component and that connect the first wiring substrate and the second wiring substrate, wherein each of the plurality of connection members includes a pair of cores that are adjacent in a lamination direction of the first wiring substrate and the second wiring substrate, and a conductor film that covers the pair of cores, and at connection members that are arrayed in at least an innermost row or an outermost row with respect to the electronic component among the plurality of connection members, one core of the pair of cores that is disposed at a position closer to the second wiring substrate is arranged so as to be offset in a direction closer to the electronic component or in a direction away from the electronic component with respect to another core of the pair of cores that is disposed at a position closer to the first wiring substrate.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a semiconductor device according to an embodiment;

FIG. 2 is a diagram illustrating one example of an arrangement of a plurality of connection members, lower cores, and upper cores according to the embodiment;

FIG. 3 is a diagram illustrating another example of an arrangement of a plurality of connection members, the lower core, and the upper core according to the embodiment;

FIG. 4 is a flowchart illustrating a method of manufacturing a first wiring substrate according to the embodiment;

FIG. 5 is a schematic diagram illustrating a cross-sectional view of the first wiring substrate;

FIG. 6 is a diagram illustrating a mounting process of an electronic component;

FIG. 7 is a diagram illustrating a specific example of a conductor ball mounting step;

FIG. 8 is a flowchart illustrating a method of manufacturing a second wiring substrate according to the embodiment;

FIG. 9 is a schematic diagram illustrating a cross-sectional view of the second wiring substrate;

FIG. 10 is a diagram illustrating a specific example of the conductor ball mounting step;

FIG. 11 is a flowchart illustrating a method of manufacturing a semiconductor device according to the embodiment;

FIG. 12 is a diagram for explaining a method of laminating the first wiring substrate and the second wiring substrate;

FIG. 13 is a diagram illustrating a specific example of a bonding step;

FIG. 14 is a diagram illustrating a specific example of a molding step;

FIG. 15 is a diagram illustrating a specific example of a dicing step;

FIG. 16 is a diagram illustrating one example of an arrangement of the plurality of connection members, the lower cores, and the upper cores according to a first modification of the embodiment;

FIG. 17 is a diagram illustrating one example of an arrangement of the plurality of connection members, the lower cores, and the upper cores according to a second modification of the embodiment;

FIG. 18 is a diagram illustrating one example of an arrangement of the plurality of connection members, the lower cores, and the upper cores according to a third modification according to the embodiment;

FIG. 19 is a diagram illustrating one example of an arrangement of the plurality of connection members, the lower cores, and the upper cores according to a fourth modification according to the embodiment;

FIG. 20 is a diagram illustrating one example of an arrangement of the plurality of connection members, the lower cores, and the upper cores according to a fifth modification of the embodiment; and

FIG. 21 is a diagram illustrating one example of an arrangement of the plurality of connection members, the lower cores, and the upper cores according to a sixth modification according to the embodiment.

### DESCRIPTION OF EMBODIMENT

Hereinafter, a preferred embodiment of a semiconductor device disclosed in the present invention will be described in detail below with reference to the accompanying drawings. Moreover, the disclosed technology is not limited by the embodiment.

### Embodiment

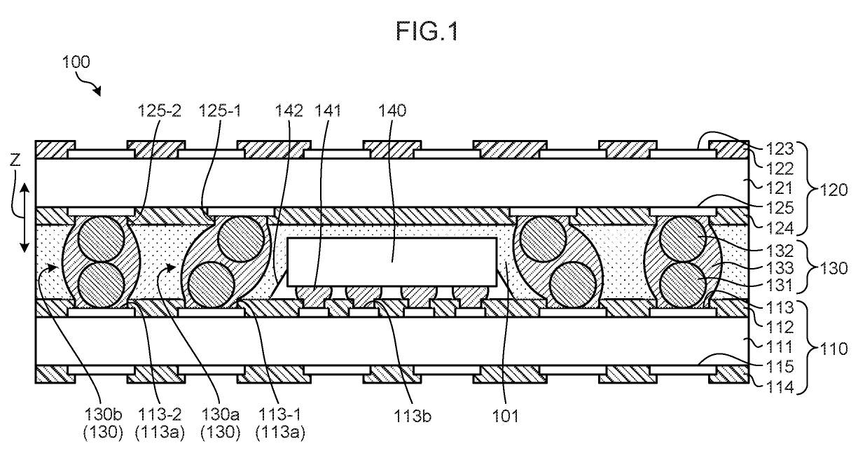

FIG. 1 is a diagram illustrating a configuration of a semiconductor device 100 according to an embodiment. In FIG. 1, a cross-sectional view of the semiconductor device 100 is schematically illustrated. Moreover, in the following, for the sake of convenience, it is assumed that a direction from a first wiring substrate 110 toward a second wiring substrate 120 is an upward direction, and a direction from the second wiring substrate 120 toward the first wiring substrate 110 is a downward direction, and a vertical direction of the semiconductor device 100 is defined in accordance with this. However, the semiconductor device 100 may be manufactured or used by, for example, vertically inverting the surfaces of the semiconductor device 100, or may be manufactured or used in an arbitrary orientation.

The semiconductor device 100 illustrated in FIG. 1 includes the first wiring substrate 110 and the second wiring substrate 120 that are laminated, and includes a sealing resin 101 that covers an electronic component 140 that is arranged by being sandwiched between the first wiring substrate 110 and the second wiring substrate 120. Specifically, the semiconductor device 100 is constituted such that the first wiring substrate 110 and the second wiring substrate 120 are connected by a plurality of connection members 130. Then, the electronic component 140 is mounted on the upper surface of the first wiring substrate 110, and the electronic component 140 is sandwiched by the first wiring substrate 110 and the second wiring substrate 120 and is covered by the sealing resin 101. The plurality of the connection members 130 are arrayed around the electronic component 140.

The sealing resin 101 is, for example, an insulation property resin, such as a thermosetting epoxy-based resin, containing an inorganic filler, such as alumina, silica, aluminum nitride, silicon carbide. The electronic component 140 is, for example, a semiconductor chip.

The first wiring substrate 110 includes a substrate 111, a protective insulating layer 112 (one example of a first insulating layer), an upper surface pad 113, a solder resist layer 114, and a lower surface pad 115. Moreover, although not illustrated in FIG. 1, the upper surface pad 113 and the lower surface pad 115 are electrically connected by a via wiring that is provided inside the substrate 111.

The substrate 111 is a member that is formed in a plate shape and that has an insulation property, and is a base material of the first wiring substrate 110. The material to be used for the substrate 111 may be, for example, a glass epoxy resin, or the like that is formed by impregnating, for example, glass cloth (a glass woven fabric) that is a reinforcement material with a thermosetting insulation-property resin made of an epoxy resin as a main component and being cured. The reinforcement material used may, in addition to the glass cloth, for example, a glass non-woven fabric, an aramid woven fabric, an aramid non-woven fabric, a liquid crystal polymer (LCP) woven fabric, a LCP non-woven fabric, or the like. Furthermore, the thermosetting insulation-property resin used may be, in addition to the epoxy resin, for example, a polyimide resin, a cyanate resin, or the like. A wiring layer that includes the upper surface pad 113 and the lower surface pad 115 is formed on both of the surfaces of the substrate 111. The material to be used for the wiring layer may be, for example, copper or a copper alloy.

Moreover, the substrate 111 is not limited to the insulation property member formed of a single layer, but may be a laminated substrate having a multi-layered structure in which the insulating layer and the wiring layer are laminated. In a case where the substrate 111 is a laminated substrate, the wiring layer that sandwiches the insulating layer is electrically connected by a via that passes through the insulating layer. The material to be used for the insulating layer may be, for example, an insulation-property resin, such as an epoxy resin or a polyimide resin, or a resin material made by mixing the epoxy resin or the polyimide resin in a filler made of silica, alumina, or the like. Furthermore, the material to be used for the wiring layer may be, for example, copper (Cu) or a copper alloy.

The protective insulating layer 112 is an insulating layer that covers the upper surface of the substrate 111. An opening portion is provided at a part of the protective insulating layer 112, and the upper surface pad 113 is exposed from the opening portion. The material to be used for the protective insulating layer 112 may be, for example, an insulation property resin, such as an epoxy-based resin or an acrylic-based resin.

The upper surface pad 113 is formed on the wiring layer disposed on the upper surface of the substrate 111, and is exposed from the opening portion provided in the protective insulating layer 112 in order to be connected to the connection member 130 and in order to mount the electronic component 140. In other words, the connection member 130 is connected to an upper surface pad 113a included in the upper surface pad 113. The upper surface pad 113a includes an inner pad 113-1 (one example of a first pad) and an outer pad 113-2. Connection members 130a that are included in the plurality of the connection members 130 and that are arrayed in an innermost row with respect to the electronic component 140 are connected to the inner pad 113-1, and connection members 130b that are located further away from the electronic component 140 than the connection members 130a are connected to the outer pad 113-2. Furthermore, the electronic component 140 is connected to an upper surface pad 113b included in the upper surface pad 113. Specifically, for example, the electronic component 140 is connected to the upper surface pad 113b by a solder bump 141 by using a flip chip connection technique. Then, an underfill material 142 is filled between the first wiring substrate 110 and the electronic component 140. The material to be used for the upper surface pad 113 may be, similarly to the wiring layer, for example, copper or a copper alloy.

The solder resist layer 114 is an insulating layer that covers the lower surface of the substrate 111. An opening portion is provided at a part of the solder resist layer 114, and the lower surface pad 115 is exposed from the opening portion. The material to be used for the solder resist layer 114 may be, for example, an insulation property resin, such as an epoxy-based resin or an acrylic-based resin.

The lower surface pad 115 is formed on the wiring layer disposed on the lower surface of the substrate 111, and is exposed from the opening portion provided in the solder resist layer 114 in order to form an external connection terminal. In other words, on the lower surface pad 115, for example, an external connection terminal (not illustrated), such as a solder ball, is formed. The material to be used for the lower surface pad 115 may be, similarly to the wiring layer, for example, copper or a copper alloy.

The second wiring substrate 120 includes a substrate 121, a solder resist layer 122, an upper surface pad 123, a protective insulating layer 124 (one example of the second insulating layer), and a lower surface pad 125. Moreover, although not illustrated in FIG. 1, the upper surface pad 123 and the lower surface pad 125 is electrically connected by a via wiring that is provided inside the substrate 121.

The substrate 121 is a member that is formed in a plate shape and that has an insulation property, and is a base material of the second wiring substrate 120. The material to be used for the substrate 121 may be, for example, a glass epoxy resin, or the like that is formed by impregnating, for example, glass cloth (a glass woven fabric) that is a reinforcement material with a thermosetting insulation-property resin made of an epoxy resin as a main component and being cured. The reinforcement material used may, in addition to the glass cloth, for example, a glass non-woven fabric, an aramid woven fabric, an aramid non-woven fabric, a LCP woven fabric, a LCP non-woven fabric, or the like. Furthermore, the thermosetting insulation-property resin used may be, in addition to the epoxy resin, for example, a polyimide resin, a cyanate resin, or the like. A wiring layer that includes the upper surface pad 123 and the lower surface pad 125 is formed on both of the surfaces of the substrate 121. The material to be used for the wiring layer may be, for example, copper or a copper alloy.

Moreover, the substrate 121 is not limited to the insulation property member formed of a single layer, but may be a laminated substrate having a multi-layered structure in which the insulating layer and the wiring layer are laminated. In a case where the substrate 121 is a laminated substrate, the wiring layer that sandwiches the insulating layer is electrically connected by a via that passes through the insulating layer. The material to be used for the insulating layer may be, for example, an insulation-property resin, such as an epoxy resin or a polyimide resin, or a resin material made by mixing the epoxy resin or the polyimide resin in a filler made of silica, alumina, or the like. Furthermore, the material to be used for the wiring layer may be, for example, copper (Cu) or a copper alloy.

The solder resist layer 122 is an insulating layer that convers the upper surface of the substrate 121. An opening portion is provided at a part of the solder resist layer 122, and the upper surface pad 123 is exposed from the opening portion. The material to be used for the solder resist layer 122 may be, for example, an insulation property resin, such as an epoxy-based resin or an acrylic-based resin.

The upper surface pad 123 is formed on the wiring layer disposed on the upper surface of the substrate 121, and is exposed from the opening portion provided in the solder resist layer 122 in order to form an external connection terminal. In other words, on the upper surface pad 123, for example, the external connection terminal (not illustrated), such as a solder ball, is formed. The material to be used for the upper surface pad 123 may be, similarly to the wiring layer, for example, copper or a copper alloy.

The protective insulating layer 124 is an insulating layer that covers the lower surface of the substrate 121. An opening portion is provided at a part of the protective insulating layer 124, and the lower surface pad 125 is exposed from the opening portion. The material to be used for the protective insulating layer 124 may be, for example, an insulation property resin, such as an epoxy-based resin or an acrylic-based resin.

The lower surface pad 125 is formed on the wiring layer disposed on the lower surface of the substrate 121, and is exposed from the opening portion provided in the protective insulating layer 124 in order to be connected to the connection member 130. In other words, the connection member 130 is bonded to the lower surface pad 125. The lower surface pad 125 includes an inner pad 125-1 (one example of a second pad) and an outer pad 125-2. The connection members 130a that are included in the plurality of the connection members 130 and that are arrayed in an innermost row with respect to the electronic component 140 are connected to the inner pad 125-1, and the connection members 130b that are located further away from the electronic component 140 than the connection member 130a are connected to the outer pad 125-2. The material to be used for the lower surface pad 125 may be, similarly to the wiring layer, for example, copper or a copper alloy.

The plurality of the connection members 130 are arrayed around the electronic component 140, and connect the first wiring substrate 110 and the second wiring substrate 120. Each of the plurality of the connection members 130 includes a lower core 131 and an upper core 132 (one example of a pair of cores) each of which is formed in a spherical shape and is adjacent to a direction that is parallel to a lamination direction Z of the first wiring substrate 110 and the second wiring substrate 120, and includes solder 133 (one example of a conductor film) that covers the lower core 131 and the upper core 132. The lower core 131 is a core that is relatively closer to the first wiring substrate 110 between the lower core 131 and the upper core 132, whereas the upper core 132 is a core that is relatively closer to the second wiring substrate 120 between the lower core 131 and the upper core 132. For the lower core 131 and the upper core 132, for example, a metal core that is made of metal, such as copper (Cu), gold (Au), or nickel (Ni), a resin core that is made of a resin, or the like may be used. For the solder 133, for example, an alloy that includes lead (Pb), an alloy of tin (Sn) and copper (Cu), an alloy of tin (Sn) and antimony (Sb), an alloy of tin (Sn) and silver (Ag), an alloy of tin (Sn), silver (Ag), and copper (Cu), or the like may be used. Each of the plurality of the connection members 130 is an integrated object that is formed by integrating the solder that is used for the conductor ball that is formed by covering the lower core 131 by the solder and that is mounted on the first wiring substrate 110 and the solder that is used for the conductor ball that is formed by covering the upper core 132 by the solder and that is mounted on the second wiring substrate 120.

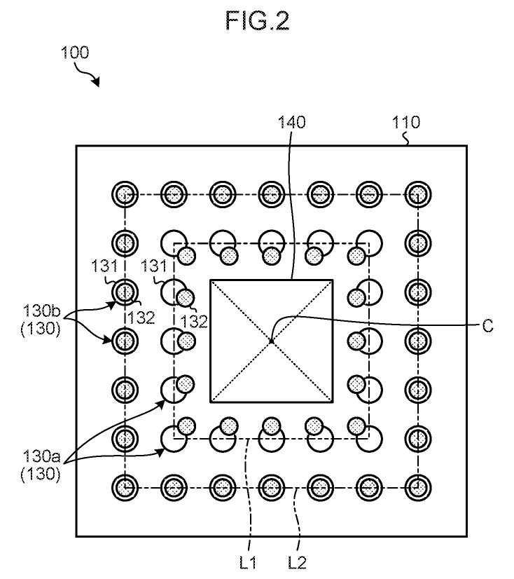

FIG. 2 is a diagram illustrating one example of an arrangement of the plurality of the connection members 130, the lower cores 131, and the upper cores 132 according to the embodiment. In FIG. 2, a top view when the semiconductor device 100 is viewed in the lamination direction Z (see FIG. 1) is illustrated. Moreover, in FIG. 2, for convenience of description, illustrations of the second wiring substrate 120, the sealing resin 101, the solder 133, and the like are omitted.

As illustrated in FIG. 2, in the semiconductor device 100 according to the embodiment, at the connection members 130a that are included in the plurality of the connection members 130 and that are arrayed in the innermost row with respect to at least the electronic component 140, the upper cores 132 are arranged so as to be offset in a direction that is closer to the electronic component 140 with respect to the lower cores 131. For example, at the 16 connection members 130a that are included in the plurality of the connection members 130 illustrated in FIG. 2 and that are arrayed in the innermost row, the upper cores 132 are arranged so as to be offset in a direction that is closer to the electronic component 140 with respect to the lower cores 131.

It is assumed that both of the positions of the upper cores 132 and the positions of the lower cores 131 are aligned in the lamination direction Z (see FIG. 1) at all of the plurality of the connection members 130. In this case, when the solder that is used for the two conductor balls that are mounted on the first wiring substrate 110 and the second wiring substrate 120 is melted by heat and a pressure and is integrated, a contact between the two conductor balls to be pressurized is a point contact, so that the two conductor balls become slippery. As a result of this, the conductor ball disposed on an upper side between the two conductor balls slides down from the conductor ball that is disposed on a lower side, and a positional shift may accordingly occur between the first wiring substrate 110 and the second wiring substrate 120 that pressurize the two conductor balls.

In contrast, in the semiconductor device 100 according to the embodiment, at the connection members 130a that are included in the plurality of the connection members 130 and that are arrayed in the innermost row, the upper cores 132 are offset in the direction that is closer to the electronic component 140 with respect to the lower cores 131. As a result of this, in a case where the solder that is used for the two conductor balls that are mounted on the first wiring substrate 110 and the second wiring substrate 120 is melted by heat and a pressure and is integrated, stress acts from the lower cores 131 onto the upper cores 132 in a direction closer to the electronic component 140, and a slip of the conductor ball disposed on the upper side is limited. Therefore, with the semiconductor device 100 according to the embodiment, it is possible to fix the positions of the two conductor balls that are mounted on the first wiring substrate 110 and the second wiring substrate 120, and, as a result of this, it is possible to suppress a positional shift between the first wiring substrate 110 and the second wiring substrate 120.

Furthermore, the plurality of the connection members 130 may be arrayed on a plurality of frame lines L1 and L2 (in this case, two) each of which surrounds an outer periphery of the electronic component 140 and also has a different distance from the center of the electronic component 140 when viewed from the lamination direction Z (see FIG. 1) in a plan view. The plurality of the frame lines L1 and L2 may have, for example, a rectangular shape. Then, at the connection members 130a that are included in the plurality of the connection members 130 and that are arrayed on the frame line L1 that is closest to the electronic component 140, the upper cores 132 may be arranged so as to be offset in a direction closer to the electronic component 140 with respect to the lower cores 131.

With this configuration, it is possible to simply limit a slip of the upper core 132 at the connection members 130a that are arrayed on the frame line L1 that is located at a position closest to the electronic component 140. Therefore, with the semiconductor device 100 having such a configuration, it is possible to fix the positions of the two conductor balls that are mounted on the first wiring substrate 110 and the second wiring substrate 120 with a simple configuration, and, as a result of this, it is possible to efficiently suppress the positional shift between the first wiring substrate 110 and the second wiring substrate 120.

Moreover, the direction in which the upper core 132 is to be offset with respect to the lower core 131 may be a direction closer to a center C of the electronic component 140 or may be a direction away from the center C of the electronic component 140. In a case where, for example, the electronic component 140 is formed in a rectangular shape when viewed form the lamination direction Z (see FIG. 1) in a plan view, the center C of the electronic component 140 may be a point of intersection of two diagonal lines on the upper surface of the electronic component 140.

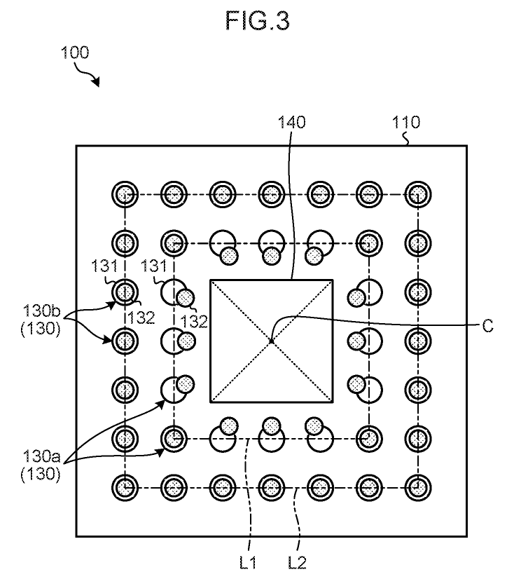

FIG. 3 is a diagram illustrating another one example of an arrangement of the plurality of the connection members 130, the lower cores 131, and the upper cores 132 according to the embodiment. In FIG. 3, a top view when the semiconductor device 100 is viewed from the lamination direction Z (see FIG. 1) is illustrated. Moreover, in FIG. 3, for convenience of description, illustrations of the second wiring substrate 120, the sealing resin 101, the solder 133, and the like are omitted.

As illustrated in FIG. 3, at the connection members 130a that are included in the plurality of the connection members 130, that are arrayed on the frame line L1 having a rectangular shape, that are closest to the electronic component 140, and also, that are not located at the four corners of the frame line L1, the upper cores 132 may be arranged so as to be offset with respect to the lower cores 131. In other words, at the connection members 130a that are located at the four corners of the frame line L1 that has a rectangular shape, the upper cores 132 do not need to be offset with respect to the lower core 131. As a result of this, it is possible to reduce a possibility of an interference between the connection members 130a that are located at the four corners of the frame line L1 having the rectangular shape and the other connection members 130a that are adjacent to the subject connection members 130a that are located at the four corners of the frame line L1.

Subsequently, a method of manufacturing the semiconductor device 100 having constituted as described above will be described. In the following, a method of manufacturing the first wiring substrate 110 and a method of manufacturing the second wiring substrate 120 will be described, and then, a method of manufacturing the semiconductor device 100 having the first wiring substrate 110 and the second wiring substrate 120 will be described.

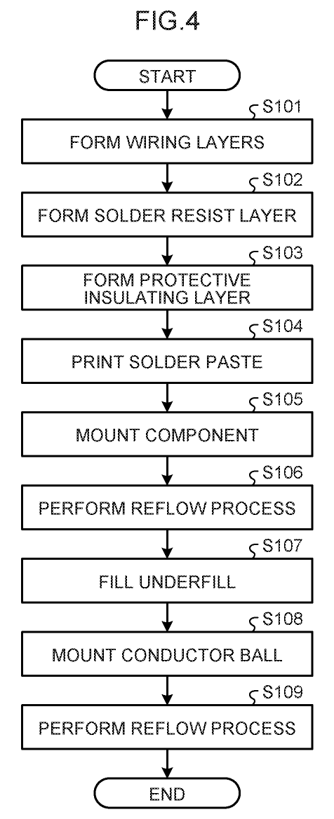

FIG. 4 is a flowchart illustrating the method of manufacturing the first wiring substrate 110 according to the embodiment.

First, the wiring layers are formed on the upper surface and the lower surface of the substrate 111 (Step S101). Specifically, for example, the wiring layers disposed on the upper surface and the lower surface of the substrate 111 are sequentially formed by using a semi-additive method. The upper surface pad 113 is included in the wiring layer disposed on the upper surface of the substrate 111, and the lower surface pad 115 is included in the wiring layer disposed on the lower surface of the substrate 111. Then, the solder resist layer 114 that includes an opening portion located at a position of the lower surface pad 115 is formed on the lower surface of the substrate 111 (Step S102), and the protective insulating layer 112 that includes an opening portion located at a position of the upper surface pad 113 is formed on the upper surface of the substrate 111 (Step S103). The protective insulating layer 112 and the solder resist layer 114 are obtained by, for example, laminating a photosensitive resin film on the upper surface and the lower surface of the substrate 111 or applying a liquid or paste resin on the upper surface and the lower surface of the substrate 111, performing a process of exposure and image development on the laminated or applied resin by using a photolithography method, and patterning to a desired shape.

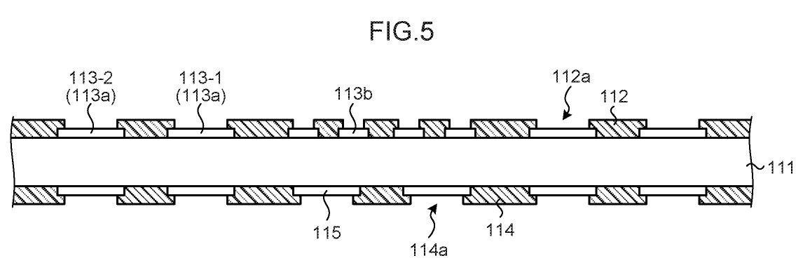

Up to the steps described above, for example, as illustrated in FIG. 5, the first wiring substrate 110 in which the upper surface pads 113a and 113b are exposed from an opening portion 112a formed in the protective insulating layer 112 that is provided on the upper surface of the substrate 111 and the lower surface pad 115 is exposed from an opening portion 114a formed in the solder resist layer 114 that is provided on the lower surface of the substrate 111 is formed. FIG. 5 is a schematic diagram illustrating a cross-sectional view of the first wiring substrate. The upper surface pad 113a is a pad that is connected to the connection members 130, and includes the inner pad 113-1 and the outer pad 113-2. The inner pad 113-1 is a pad that is connected to the connection members 130a that are included in the plurality of the connection members 130 and that are arrayed in the innermost row with respect to the electronic component 140, whereas the outer pad 113-2 is a pad that is connected to the connection members 130b that are located at a position away from the electronic component 140 than the connection member 130a. The upper surface pad 113b is a pad that connects the electronic component 140 by using a flip chip connection technique. The areas in which the upper surface pads 113a and 113b are exposed may be different with each other. Furthermore, the width of a portion in which the upper surface pad 113a is exposed may be set to about, for example, 120 to 160 μm.

The electronic component 140 is mounted on the upper surface pad 113b, so that a solder paste is printed (Step S104). Then, the electronic component 140 is mounted on the position of the upper surface pad 113b (Step S105). The electronic component 140 is subjected to a reflow process (Step S106), and is then mounted on the first wiring substrate 110. Furthermore, the underfill material 142 made of the insulation property resin is filled between the electronic component 140 and the upper surface of the first wiring substrate 110 as needed (Step S107).

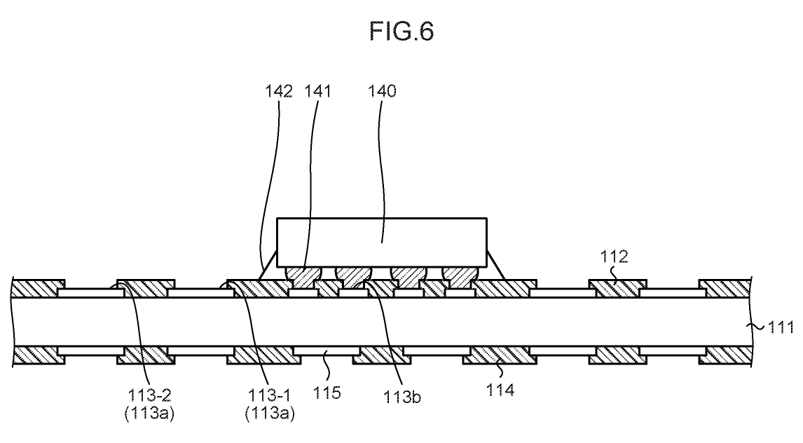

Up to the steps described above, for example, as illustrated in FIG. 6, the electronic component 140 that is connected to upper surface pad 113b by the solder bump 141 by using the flip chip connection technique is mounted on the upper surface of the first wiring substrate 110. FIG. 6 is a diagram illustrating a mounting process of the electronic component 140.

When the electronic component 140 is mounted on the upper surface of the first wiring substrate 110, a conductor ball 130A (one example of a first conductor ball) that is used to form the connection member 130 is mounted at the position of the upper surface pad 113a (Step S108). The conductor ball 130A is formed by covering the lower core 131 by the solder 133. Then, as a result of the reflow process being performed (Step S109), the conductor ball 130A is bonded to the upper surface pad 113a by the solder 133 disposed around the lower core 131.

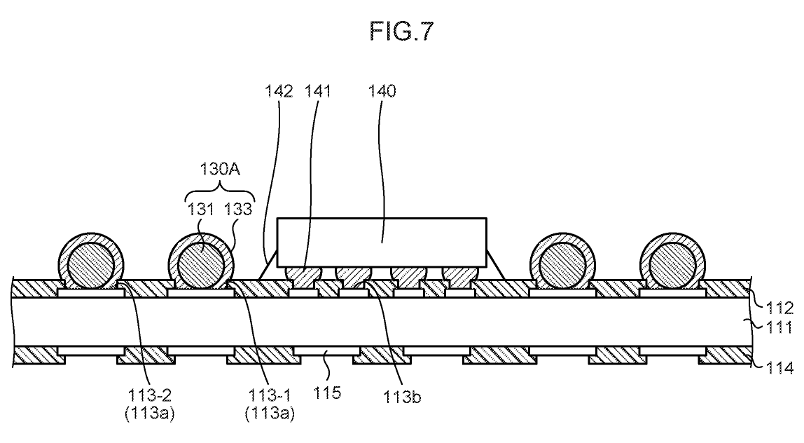

Up to the steps described above, for example, as illustrated in FIG. 7, the conductor ball 130A is bonded to the upper surface pad 113a. As a result of this, the first wiring substrate 110 that forms a lower layer of the semiconductor device 100 is obtained. FIG. 7 is a diagram illustrating a specific example of a conductor ball mounting step. The electronic component 140 is mounted on the upper surface of the obtained first wiring substrate 110, and the conductor ball 130A is bonded to the upper surface pad 113a that is exposed from the opening portion formed in the protective insulating layer 112. The diameter of the conductor ball 130A may be set to about, for example, 100 to 250 μm.

Moreover, it is preferable that the first wiring substrate 110 is manufactured as an aggregate object such that the plurality of the first wiring substrates 110 are arrayed, instead of being manufactured as a single unit. In the aggregate object, for example, the first wiring substrate 110 is manufactured in individual sections that are divided into a grid shape.

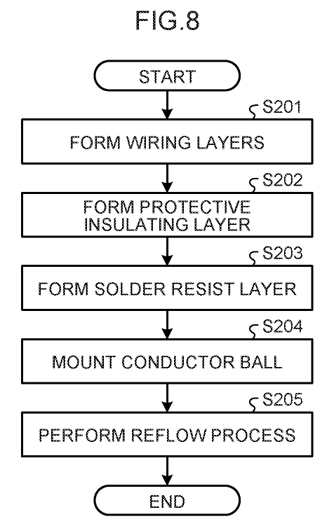

In the following, FIG. 8 is a flowchart illustrating a method of manufacturing the second wiring substrate 120 according to the embodiment.

First, a wiring layer is formed on each of the upper surface and the lower surface of the substrate 121 (Step S201). Specifically, for example, the wiring layers formed on the upper surface and the lower surface of the substrate 121 are sequentially formed by using the semi-additive method. The upper surface pad 123 is included in the wiring layer formed on the upper surface of the substrate 121, and the lower surface pad 125 is included in the wiring layer formed on the lower surface of the substrate 121. Then, the protective insulating layer 124 that includes an opening portion is formed on the lower surface of the substrate 121 at the position of the lower surface pad 125 (Step S202), and the solder resist layer 122 that includes an opening portion is formed on the upper surface of the substrate 121 at the position of the upper surface pad 123 (Step S203). The solder resist layer 122 and the protective insulating layer 124 are obtained by, for example, laminating a photosensitive resin film on the upper surface and the lower surface of the substrate 121 or applying a liquid or paste resin on the upper surface and the lower surface of the substrate 111, performing a process of exposure and image development on the laminated or applied resin by using a photolithography method, and patterning to a desired shape.

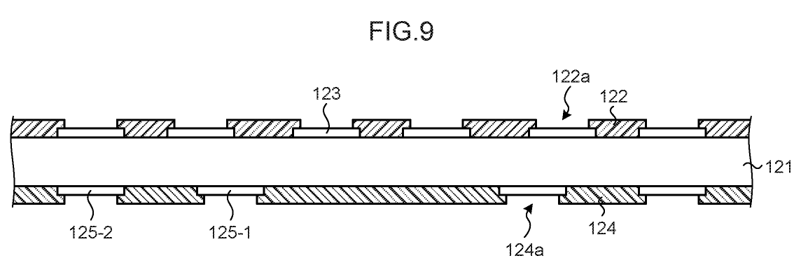

Up to the steps described above, for example, as illustrated in FIG. 9, the second wiring substrate 120 in which the upper surface pad 123 is exposed from an opening portion 122a formed in the solder resist layer 122 on the upper surface of the substrate 121 and the lower surface pad 125 is exposed from an opening portion 124a formed in the protective insulating layer 124 on the lower surface of the substrate 121 is formed. FIG. 9 is a schematic diagram illustrating a cross-sectional view of the second wiring substrate. The lower surface pad 125 is a pad that is connected to the connection member 130, and includes the inner pad 125-1 and the outer pad 125-2. The inner pad 125-1 is a pad that is connected to the connection members 130a that are included in the plurality of the connection members 130 and that are arrayed in the innermost row with respect to the electronic component 140, and the outer pad 125-2 is a pad that is connected to the connection members 130b that are located at a position away from the electronic component 140 than the connection member 130a.

Furthermore, the inner pad 125-1 is arranged so as to be offset in the direction closer to the electronic component 140 with respect to the inner pad 113-1. As a result of this, it is possible to offset the position of the inner pad 125-1 to the position suitable for a connection to the connection members 130a that are arrayed in the innermost row with respect to the electronic component 140.

Furthermore, the opening portion 124a formed in the protective insulating layer 124 is arranged so as to be offset in the direction closer to the electronic component 140 with respect to the opening portion 112a formed in the protective insulating layer 112. As a result of this, it is possible to keep the area of the inner pad 125-1 that is exposed from the opening portion 124a formed in the protective insulating layer 124 to the area that is suitable for a connection to the connection members 130a that are arrayed in the innermost row with respect to the electronic component 140.

The connection member 130 is connected to the lower surface pad 125, so that a conductor ball 130B (one example of a second conductor ball) that is used to form the connection member 130 is mounted at the position of the lower surface pad 125 (Step S204). The conductor ball 130B is formed by covering the upper core 132 by the solder 133. Then, as a result of the reflow process being performed (Step S205), the conductor ball 130B is bonded to the lower surface pad 125 by the solder 133 disposed around the upper core 132.

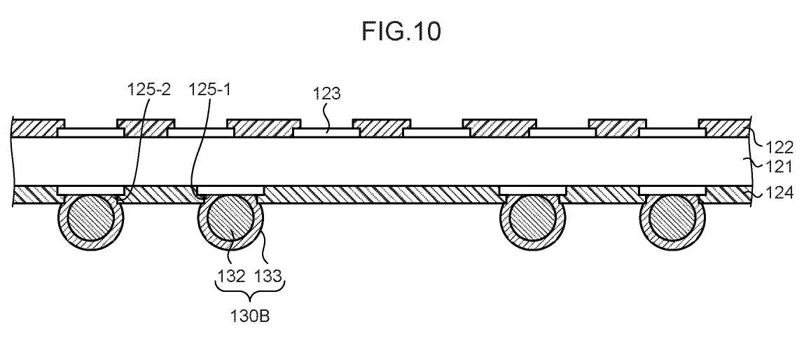

Up to the steps described above, for example, as illustrated in FIG. 10, the conductor ball 130B is bonded to the lower surface pad 125. As a result of this, the second wiring substrate 120 that forms an upper layer of the semiconductor device 100 is obtained. FIG. 10 is a diagram illustrating a specific example of a conductor ball mounting step. The conductor ball 130B is bonded to the lower surface pad 125 that is exposed from the opening portion formed in the protective insulating layer 124 on the obtained second wiring substrate 120. The diameter of the conductor ball 130B may be set to about, similarly to the conductor ball 130A, for example, 100 to 250 μm. The diameter of the conductor ball 130B may be different from the diameter of the conductor ball 130A.

Moreover, it is preferable that the second wiring substrate 120 is manufactured as an aggregate object such that the plurality of the second wiring substrates 120 are arrayed, instead of being manufactured as a single unit. In the aggregate object, for example, the second wiring substrate 120 is manufactured in individual sections that are divided into a grid shape.

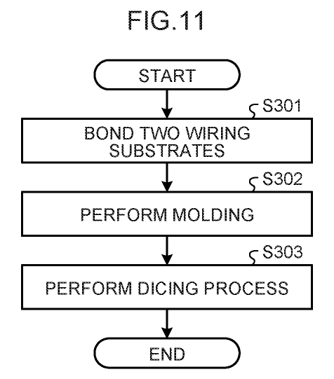

In the following, FIG. 11 is a flowchart illustrating a method of manufacturing the semiconductor device 100 according to the embodiment. The semiconductor device 100 is manufactured by using the first wiring substrate 110 and the second wiring substrate 120 described above.

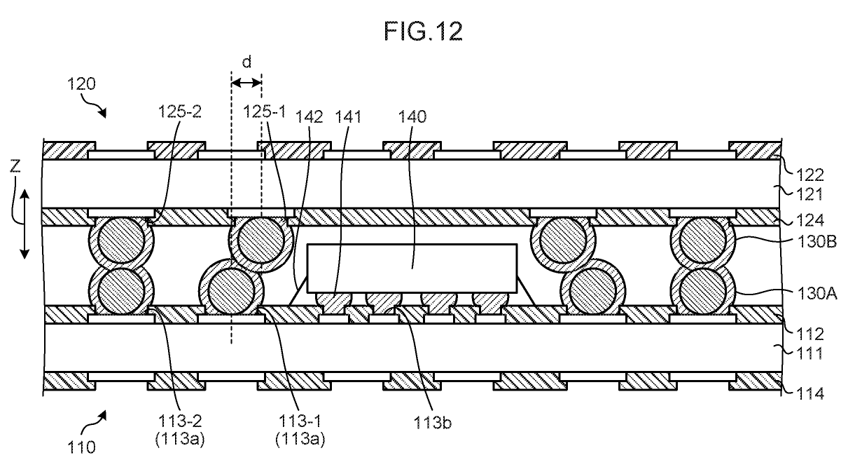

The first wiring substrate 110 and the second wiring substrate 120 are bonded by using, for example, a Thermal Compression Bonding (TCB) technique (Step S301). First, for example, as illustrated in FIG. 12, the conductor ball 130B that is bonded to the lower surface pad 125 included in the second wiring substrate 120 is arranged on the conductor ball 130A that is bonded to the upper surface pad 113a included in the first wiring substrate 110, and the second wiring substrate 120 is laminated on the first wiring substrate 110. FIG. 12 is a diagram illustrating a method of laminating the first wiring substrate 110 and the second wiring substrate 120. The electronic component 140 is arranged between the first wiring substrate 110 and the second wiring substrate 120. The inner pad 125-1 included in the second wiring substrate 120 is arranged so as to be offset in the direction closer to the electronic component 140 with respect to the inner pad 113-1 included in the first wiring substrate 110. The conductor ball 130B that is bonded to the inner pad 125-1 included in the second wiring substrate 120 is arranged so as to be offset in the direction closer to the electronic component 140 with respect to the conductor ball 130A that is bonded to the inner pad 113-1 included in the first wiring substrate 110.

It is preferable that an offset amount d of the upper core 132 with respect to the lower core 131 is smaller than the diameter of the conductor ball 130A or the conductor ball 130B in terms of allowing an appropriate integration of the solder 133 that is used for the conductor ball 130A and the solder 133 that is used for the conductor ball 130B. For example, the offset amount d may be set to about 1 to 10% of the diameter of the conductor ball 130A or the conductor ball 130B. In a case where the diameter of the conductor ball 130A and the diameter of the conductor ball 130B are different each other, the offset amount d is adjusted on the basis of the diameter of the conductor ball having a larger diameter. Furthermore, in a case where the diameter of the conductor ball 130A and the diameter of the conductor ball 130B are different each other, flexibility of a design is higher in the second wiring substrate 120 in which the electronic component is not mounted and the underfill material is not also formed, so that it is preferable that the diameter of the conductor ball 130B is set to be larger than the diameter of the conductor ball 130A.

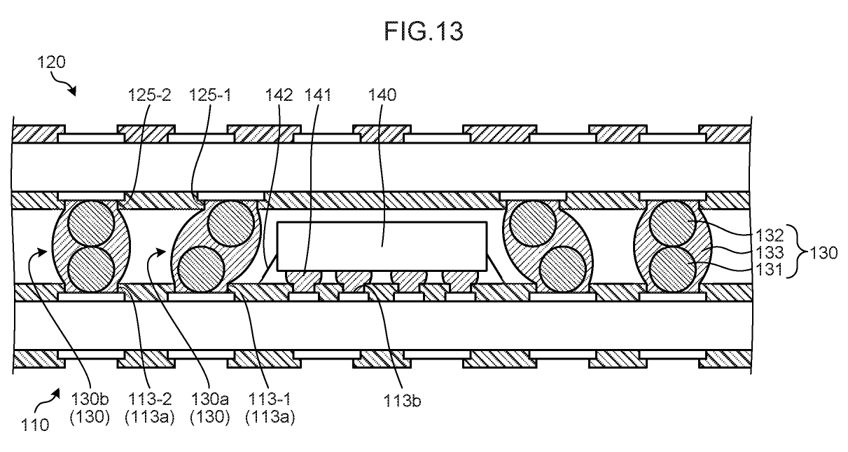

Subsequently, the solder 133 that is used for the conductor ball 130A and the solder 133 that is used for the conductor ball 130B are integrated by being melted by heat and a pressure, and each of the connection members 130 that includes the lower core 131, the upper core 132, and the solder 133 is formed. As a result of this, for example, as illustrated in FIG. 13, the first wiring substrate 110 and the second wiring substrate 120 are bonded by the plurality of the connection members 130. At this time, stress acts from the lower core 131 onto the upper core 132 in a direction closer to the electronic component 140 caused by the offset between the conductor ball 130B that is bonded to the inner pad 125-1 and the conductor ball 130A that is bonded to the inner pad 113-1. As a result of this, a slip of the conductor ball 130B disposed on the upper side is limited, so that it is possible to fix the position of the two conductor balls 130A and 130B that are mounted on the first wiring substrate 110 and the second wiring substrate 120. As a result of this, it is possible to suppress a positional shift between the first wiring substrate 110 and the second wiring substrate 120. FIG. 13 is a diagram illustrating a specific example of a bonding step.

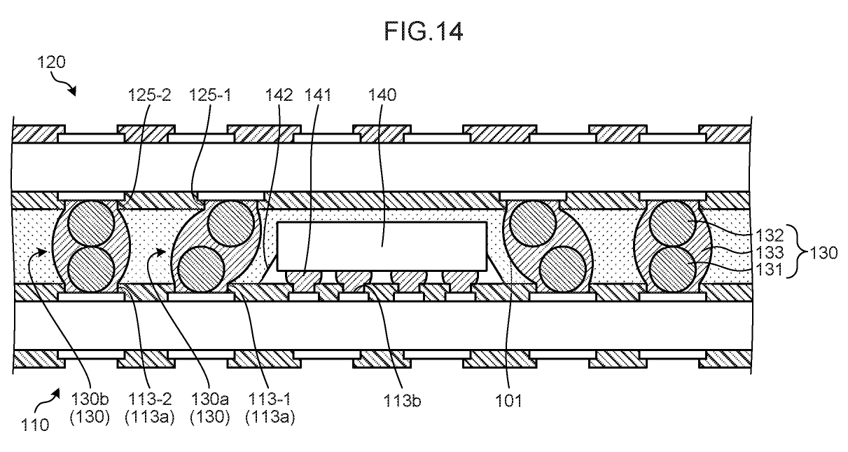

After that, for example, as a result of transformer molding being performed (Step S302), the sealing resin 101 is filled in a gap located between the first wiring substrate 110 and the second wiring substrate 120. In the transformer molding, the first wiring substrate 110 and the second wiring substrate 120 that are bonded each other are accommodated in a metal mold, the fluidized sealing resin 101 is injected into the metal mold. Then, the sealing resin 101 is heated to a predetermined temperature (for example, 175 degrees) and hardened. As a result of this, for example, as illustrated in FIG. 14, the sealing resin 101 is filled in the gap located between the first wiring substrate 110 and the second wiring substrate 120, and the connection member 130 and the electronic component 140 are sealed. FIG. 14 is a diagram illustrating a specific example of a molding step.

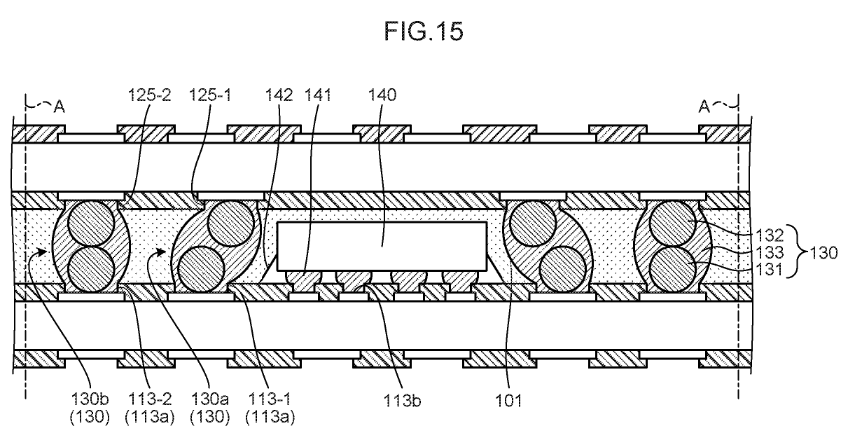

Up to the steps described above, for example, as illustrated in FIG. 14, a structure object having the same structure as that of the semiconductor device 100 is obtained. This structure object is constituted of an aggregate object that includes the plurality of the first wiring substrates 110 and an aggregate object that includes the plurality of the second wiring substrates 120, so that a dicing process of cutting out each of the first wiring substrate 110 and the second wiring substrate 120 is performed (Step S303). FIG. 15 is a diagram illustrating a specific example of a dicing step. Specifically, the structure object illustrated in FIG. 15 is cut by, for example, a dicer or a slicer at a cutting line A located on an outer side of the connection member 130b, whereby the semiconductor device 100 is obtained.

### Modification

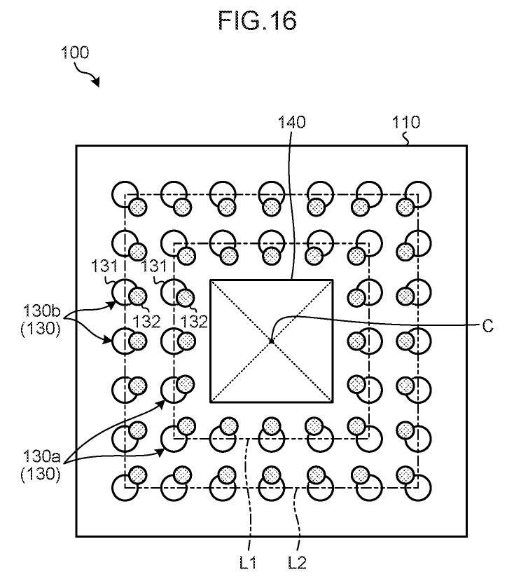

In the following, various kinds of modifications of the embodiment will be described with reference to FIG. 16 to FIG. 21. Moreover, in the modifications that will be described below, by assigning the same reference numerals to the same components as those described in the embodiment, overlapping descriptions thereof will be sometimes omitted.

FIG. 16 is a diagram illustrating one example of an arrangement of the plurality of the connection members 130, the lower cores 131, and the upper cores 132 according to the first modification of the embodiment. FIG. 16 illustrates a top view of the semiconductor device 100 when viewed from the lamination direction Z (see FIG. 1). Moreover, in FIG. 16, for convenience of description, illustrations of the second wiring substrate 120, the sealing resin 101, the solder 133, and the like are omitted.

As illustrated in FIG. 16, in the semiconductor device 100 according to the first modification, at all of the plurality of the connection members 130, the upper cores 132 are arranged so as to be offset in a direction closer to the electronic component 140 with respect to the lower cores 131.

With this configuration, it is possible to more stably fix the positions of the two conductor balls that are mounted on the first wiring substrate 110 and the second wiring substrate 120, and, as a result of this, it is possible to further suppress the positional shift between the first wiring substrate 110 and the second wiring substrate 120.

Moreover, the direction in which the upper core 132 is to be offset with respect to the lower core 131 may be a direction closer to the center C of the electronic component 140 or a direction away from the center C of the electronic component 140. In a case where, for example, the electronic component 140 is formed in a rectangular shape when viewed form the lamination direction Z (see FIG. 1) in a plan view, the center C of the electronic component 140 may be a point of intersection of two diagonal lines on the upper surface of the electronic component 140.

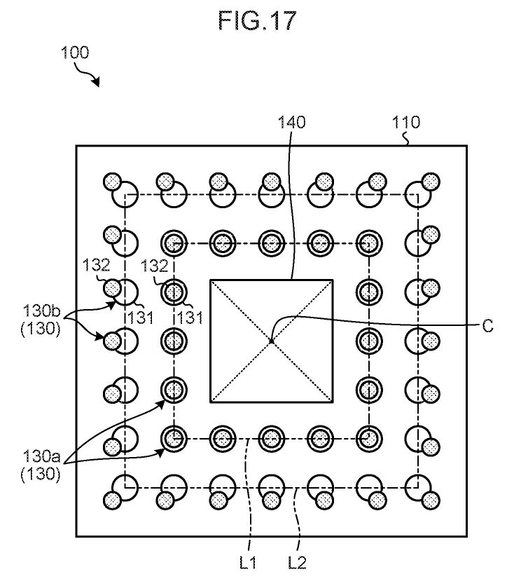

FIG. 17 is a diagram illustrating one example of an arrangement of the plurality of the connection members 130, the lower cores 131, and the upper cores 132 according to a second modification of the embodiment. FIG. 17 illustrates a top view of the semiconductor device 100 when viewed from the lamination direction Z (see FIG. 1). Moreover, in FIG. 17, for convenience of description, illustrations of the second wiring substrate 120, the sealing resin 101, the solder 133, and the like are omitted.

As illustrated in FIG. 17, in the semiconductor device 100 according to the second modification, at the connection members 130b that are included in the plurality of the connection members 130 and that are arrayed at least in the outermost row with respect to the electronic component 140, the upper cores 132 are arranged so as to be offset in a direction away from the electronic component 140 with respect to the lower cores 131. For example, in the 24 connection members 130a that are arrayed in the outermost row from among the plurality of the connection members 130 illustrated in FIG. 17, the upper cores 132 are arranged so as to be offset in a direction closer to the electronic component 140 with respect to the lower cores 131.

With this configuration, when the solder that is used for the two conductor balls that are mounted on the first wiring substrate 110 and the second wiring substrate 120 is melted by heat and a pressure and is integrated, stress acts from the lower core 131 to the upper core 132 in a direction away from the electronic component 140, and a slip of the conductor ball disposed on the upper side is limited. Therefore, with the semiconductor device 100 having this configuration, it is possible to fix the positions of the two conductor balls that are mounted on the first wiring substrate 110 and the second wiring substrate 120, and, as a result of this, it is possible to suppress a positional shift between the first wiring substrate 110 and the second wiring substrate 120.

Furthermore, in the semiconductor device 100 according to the second modification, at the connection members 130b that are included in the plurality of the connection members 130 and that are arrayed on the frame line L2 that is disposed farthest from the electronic component 140, the upper cores 132 may be arranged so as to be offset in a direction closer to the electronic component 140 with respect to the lower cores 131.

With this configuration, it is possible to simply limit a slip of the upper cores 132 at the connection members 130b that are arrayed on the frame line L2 that is disposed farthest from the electronic component 140. Therefore, with the semiconductor device 100 having this configuration, it is possible to fix the positions of the two conductor balls that are mounted on the first wiring substrate 110 and the second wiring substrate 120 with the simple configuration, and, as a result of this, it is possible to efficiently suppress the positional shift between the first wiring substrate 110 and the second wiring substrate 120.

Moreover, the direction in which the upper core 132 is to be offset with respect to the lower core 131 may be a direction closer to the center C of the electronic component 140 or may be a direction away from the center C of the electronic component 140. In a case where, for example, the electronic component 140 is formed in a rectangular shape when viewed form the lamination direction Z (see FIG. 1) in a plan view, the center C of the electronic component 140 may be a point of intersection of two diagonal lines on the upper surface of the electronic component 140.

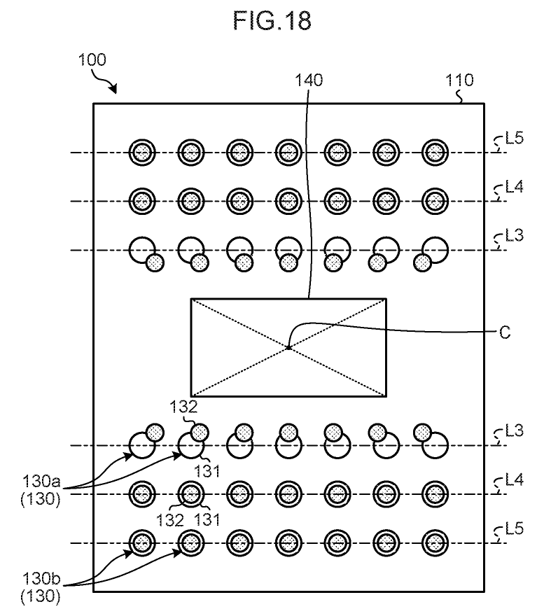

FIG. 18 is a diagram illustrating one example of an arrangement of the plurality of the connection members 130, the lower cores 131, and the upper cores 132 according to a third modification of the embodiment. FIG. 18 illustrates a top view of the semiconductor device 100 when viewed from the lamination direction Z (see FIG. 1). Moreover, in FIG. 17, for convenience of description, illustrations of the second wiring substrate 120, the sealing resin 101, the solder 133, and the like are omitted.

In the semiconductor device 100 according to the third modification, the plurality of the connection members 130 are arrayed on a plurality of straight lines L3 to L5 that extend along the two side surfaces of the electronic component 140 disposed opposite each other and each of which has a different distance from the center of the electronic component 140 when viewed from the lamination direction Z (see FIG. 1) in a plan view. Then, at the connection members 130a that are included in the plurality of the connection members 130 and that are arrayed at a position closest to the electronic component 140 on the straight line L3, the upper cores 132 are arranged so as to be offset in a direction closer to the electronic component 140 with respect to the lower cores 131.

With this configuration, it is possible to simply limit a slip of the upper cores 132 at the connection members 130a that are arrayed at a position closest to the electronic component 140 on the straight line L3. Therefore, with the semiconductor device 100 having this configuration, it is possible to fix the positions of the two conductor balls that are mounted on the first wiring substrate 110 and the second wiring substrate 120 with the simple configuration, and, as a result of this, it is possible to efficiently suppress the positional shift between the first wiring substrate 110 and the second wiring substrate 120.

Moreover, in the third modification, a case has been described as an example in which, at the connection members 130a that are arrayed at a position closest to the electronic component 140 on the straight line L3, the upper cores 132 are offset in the direction closer to the electronic component 140, but the offset of the upper cores 132 is not limited to this. For example, at the connection members 130b that are included in the plurality of the connection members 130 and that are array on the straight line L5 that is disposed farthest from the electronic component 140, the upper cores 132 may be arranged so as to be offset in a direction away from the electronic component 140 with respect to the lower cores 131.

Furthermore, the direction in which the upper cores 132 are offset with respect to the lower cores 131 may be a direction closer to the center C of the electronic component 140 or a direction away from the center C of the electronic component 140. In a case where, for example, the electronic component 140 is formed in a rectangular shape when viewed form the lamination direction Z (see FIG. 1) in a plan view, the center C of the electronic component 140 may be a point of intersection of two diagonal lines on the upper surface of the electronic component 140.

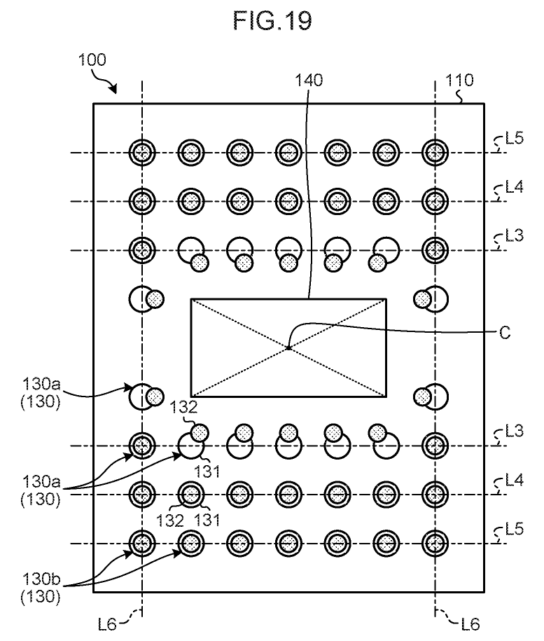

FIG. 19 is a diagram illustrating one example of an arrangement of the plurality of the connection members 130, the lower cores 131, and the upper cores 132 according to a fourth modification of the embodiment. FIG. 19 illustrates a top view of the semiconductor device 100 when viewed from the lamination direction Z (see FIG. 1). Moreover, in FIG. 19, for convenience of description, illustrations of the second wiring substrate 120, the sealing resin 101, the solder 133, and the like are omitted.

In the semiconductor device 100 according to the fourth modification, the plurality of the connection members 130 are arrayed on the plurality of the straight lines L3 to L5, and another plurality of straight lines L6 extend along another two side surfaces of the electronic component 140 disposed opposite to each other when viewed from the lamination direction Z (see FIG. 1) in a plan view. Then, at the connection members 130a that are included in the plurality of the connection members 130 and that are arrayed on the straight lines L3 and on the other straight lines L6 that are closest to the electronic component 140, the upper cores 132 are arranged so as to be offset in a direction closer to the electronic component 140 with respect to the lower cores 131.

With this configuration, it is possible to simply limit a slip of the upper cores 132 at the connection members 130a that are array on the straight lines L3 and the other straight lines L6 that are closest to the electronic component 140. Therefore, with the semiconductor device 100 having this configuration, it is possible to fix the positions of the two conductor balls that are mounted on the first wiring substrate 110 and the second wiring substrate 120 with the simple configuration, and, as a result of this, it is possible to efficiently suppress the positional shift between the first wiring substrate 110 and the second wiring substrate 120.

Moreover, in the fourth modification, a case has been described as an example in which, at the connection members 130a that are arrayed on the straight lines L3 and the other straight lines L6 that are closest to the electronic component 140, the upper cores 132 are offset in the direction closer to the electronic component 140, but the offset of the upper cores 132 is not limited to this. For example, at the connection members 130a that are included in the plurality of the connection members 130 and that are arrayed on the straight lines L3 and the other straight lines L6 that are closest to the electronic component 140, the upper cores 132 may be arranged so as to be offset in a direction away from the electronic component 140 with respect to the lower cores 131.

Furthermore, in the fourth modification, at the connection members 130a that are located at an intersection of straight lines L3 and the other straight lines L6 that are closest to the electronic component 140, there is no need for the upper cores 132 to be offset with respect to the lower cores 131. As a result of this, it is possible to reduce the possibility of an interference between the connection members 130a that are located on the straight lines L3 and the other straight lines L6 and the other connection members 130a that are adjacent to the subject connection members 130a located on the straight lines L3 and the other straight lines L6.

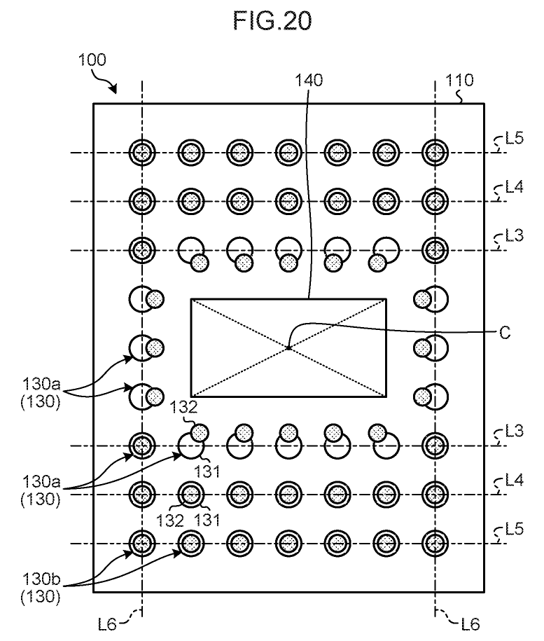

FIG. 20 is a diagram illustrating one example of an arrangement of the plurality of the connection members 130, the lower cores 131 and the upper cores 132 according to a fifth modification of the embodiment. FIG. 20 illustrates a top view of the semiconductor device 100 when viewed from the lamination direction Z (see FIG. 1). Moreover, in FIG. 20, for convenience of description, illustrations of the second wiring substrate 120, the sealing resin 101, the solder 133, and the like are omitted.

In the semiconductor device 100 according to the fifth modification, the plurality of the connection members 130 are arrayed on the plurality of the straight lines L3 to L5 and the other of the plurality of the straight lines L6 and surround an outer periphery of the electronic component 140 when viewed from the lamination direction Z (see FIG. 1) in a plan view.

With this configuration, it is possible to simply limit a slip of the upper cores 132 at the connection members 130a that are arrayed on the straight lines L3 and the other straight lines L6 that are closest to the electronic component 140. Therefore, with the semiconductor device 100 having this configuration, it is possible to fix the positions of the two conductor balls that are mounted on the first wiring substrate 110 and the second wiring substrate 120 with the simple configuration, and, as a result of this, it is possible to efficiently suppress the positional shift between the first wiring substrate 110 and the second wiring substrate 120.

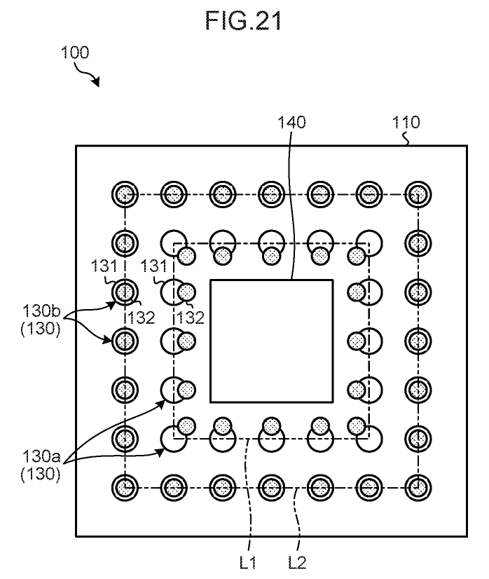

FIG. 21 is a diagram illustrating one example of an arrangement of the plurality of the connection members 130, the lower cores 131, and the upper cores 132 according to a sixth modification of the embodiment. FIG. 21 illustrates a top view of the semiconductor device 100 when viewed from the lamination direction Z (see FIG. 1). Moreover, in FIG. 21, for convenience of description, illustrations of the second wiring substrate 120, the sealing resin 101, the solder 133, and the like are omitted.

The arrangement of the plurality of the connection members 130, the lower cores 131, and the upper cores 132 illustrated in FIG. 21 is related to a variation of the arrangement of the plurality of the connection members 130, the lower cores 131, and the upper cores 132 illustrated in FIG. 2.

In FIG. 2, a case has been described as an example in which the direction in which the upper cores 132 are offset with respect to the lower cores 131 is the direction closer to the center C of the electronic component 140, but the direction in which the upper cores 132 are offset with respect to the lower cores 131 is not limited to the direction closer to the center C of the electronic component 140. For example, as illustrated in FIG. 21, the direction in which the upper cores 132 are offset with respect to the lower cores 131 may be a direction closer to each of the side surfaces of the electronic component 140.

As described above, the semiconductor device according to the embodiment (as one example, the semiconductor device 100) includes the first wiring substrate (as one example, the first wiring substrate 110), the electronic component (as one example, the electronic component 140), the second wiring substrate (as one example, the second wiring substrate 120), and the plurality of connection members (as one example, the connection members 130). The electronic component is provided on the first wiring substrate. The second wiring substrate is laminated on the first wiring substrate by sandwiching the electronic component. The plurality of connection members are arrayed around the electronic component and connect the first wiring substrate and the second wiring substrate. Each of the plurality of connection members includes the pair of cores (as one example, the lower core 131 and the upper core 132) that are adjacent in the lamination direction (as one example, the lamination direction Z) of the first wiring substrate and the second wiring substrate, and the conductor film (as one example, the solder 133) that covers the pair of cores. At the connection members (as one example, the connection members 130a and 130b) that are arrayed in at least the innermost row or the outermost row with respect to the electronic component from among the plurality of connection members, one of the cores (as one example, the upper core 132) that is disposed at a position closer to the second wiring substrate between the pair of cores is arranged so as to be offset in a direction closer to the electronic component or in a direction away from the electronic component with respect to the other core (as one example, the lower core 131) that is disposed at a position closer to the first wiring substrate. As a result of this, it is possible to suppress a positional shift between the two wiring substrates.

Furthermore, the plurality of connection members may be arrayed on the plurality of frame lines (as one example, the frame lines L1 and L2) each of which surrounds the outer periphery of the electronic component and also has a different distance from the center of the electronic component when viewed from the lamination direction in a plan view. At the connection members (as one example, the connection members 130a and 130b) that are included in the plurality of connection members and that are arrayed on the frame line (as one example, the frame line L1) that is closest to the electronic component or that are arrayed on the frame line (as one example, the frame line L2) that is disposed farthest from the electronic component, the one core may be arranged so as to be offset in the direction closer to the electronic component or in the direction away from the electronic component with respect to the other core. As a result of this, it is possible to efficiently suppress the positional shift between the two wiring substrates.

Furthermore, the plurality of connection members may be arrayed on the plurality of straight lines (as one example, the straight lines L3 to L5) each of which extends along the two opposing side surfaces of the electronic component and also has a different distance from the center of the electronic component when viewed from the lamination direction in a plan view. At the connection members (as one example, the connection members 130a and 130b) that are included in the plurality of connection members and that are arrayed on the straight line (as one example, the straight line L3) that is disposed at a position closest to the electronic component or arrayed on the straight line (as one example, the straight line L5) that is disposed farthest from the electronic component, the one core may be arranged so as to be offset in the direction closer to the electronic component or in the direction away from the electronic component with the other core. As a result of this, it is possible to efficiently suppress the positional shift between the two wiring substrates.

Furthermore, the plurality of connection members may be arrayed on the plurality of straight lines or on another plurality of straight lines (as one example, the straight line L6) that extend along another two opposing side surfaces of the electronic component when viewed from the lamination direction in a plan view. At the connection members (as one example, the connection members 130a) that are included in the plurality of connection members and that are arrayed on the straight line or on the other straight line that is closest to the electronic component, the one core may be arranged so as to be offset in the direction closer to the electronic component or in the direction away from the electronic component with respect to the other core. As a result of this, it is possible to efficiently suppress the positional shift between the two wiring substrates.

Furthermore, at all of the plurality of connection members, the one core may be arranged so as to be offset in the direction closer to the electronic component or in the direction away from the electronic component with respect to the other core. As a result of this, it is possible to further suppress the positional shift between the two wiring substrates.

Furthermore, the first wiring substrate may include the first pad (as one example, the inner pad 113-1) that is connected to the connection members that are arrayed in the innermost row or the outermost row with respect to the electronic component. The second wiring substrate may include the second pad (as one example, the inner pad 125-1) that is connected to the connection members that are arrayed in the innermost row or the outermost row with respect to the electronic component. The second pad may be arranged so as to be offset in the direction closer to the electronic component or in the direction away from the electronic component with respect to the first pad. As a result of this, it is possible to offset the position of the second pad to a position suitable for a connection to the connection members that are arrayed in the innermost row with respect to the electronic component.

Furthermore, the first wiring substrate may include the first insulating layer (as one example, the protective insulating layer 112) that covers the upper surface of the base material (as one example, the substrate 111) of the first wiring substrate and that includes the opening portion (as one example, the opening portion 112a) that allows the first pad to be exposed. The second wiring substrate may include the second insulating layer (as one example, the protective insulating layer 124) that covers the lower surface of the base material (as one example, the substrate 121) of the second wiring substrate and that includes the opening portion (as one example, the opening portion 124a) that allows the second pad to be exposed. The opening portion included in the second insulating layer may be arranged so as to be offset in a direction closer to the electronic component or in a direction away from the electronic component with respect to the opening portion included in the first insulating layer. As a result of this, it is possible to keep the area of the second pad that is exposed from the opening portion included in the second insulating layer to the area suitable for a connection to the connection members that are arrayed in the innermost row with respect to the electronic component.

Furthermore, each of the plurality of connection members may be an integrated object that is formed by integrating the conductor film used for the first conductor ball (as one example, the conductor ball 130A) that is formed by covering the one core by the conductor film and that is mounted on the first wiring substrate and the conductor film used for the second conductor ball (as one example, the conductor ball 130B) that is formed by covering the other core by the conductor film and that is mounted on the second wiring substrate. The offset amount (as one example, the offset amount d) of the one core with respect to the other core may be smaller than the diameter of the first conductor ball or the second conductor ball. As a result of this, it is possible to appropriately integrate the conductor film covering the first conductor ball and the conductor film covering the second conductor ball.

According to an aspect of one embodiment of the semiconductor device disclosed in the present application, an advantage is provided in that it is possible to suppress a positional shift between the two wiring substrates.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A semiconductor device comprising:
a first wiring substrate;
an electronic component that is provided on the first wiring substrate;
a second wiring substrate that is laminated on the first wiring substrate by sandwiching the electronic component; and
a plurality of connection members that are arrayed around the electronic component and that connect the first wiring substrate and the second wiring substrate, wherein
each of the plurality of connection members includes
a pair of cores that are adjacent in a lamination direction of the first wiring substrate and the second wiring substrate, and
a conductor film that covers the pair of cores, and
at connection members that are arrayed in at least an innermost row or an outermost row with respect to the electronic component among the plurality of connection members, one core of the pair of cores that is disposed at a position closer to the second wiring substrate is arranged so as to be offset in a direction closer to the electronic component or in a direction away from the electronic component with respect to another core of the pair of cores that is disposed at a position closer to the first wiring substrate.

2. The semiconductor device according to claim 1, wherein
the plurality of connection members are, in a plan view from the lamination direction, arrayed on a plurality of frame lines each of which surrounds an outer periphery of the electronic component and that have different distances from a center of the electronic component, and
at connection members that are arrayed on the frame line that is closest to the electronic component or on the frame line that is disposed farthest from the electronic component among the plurality of connection members, the one core is arranged so as to be offset in the direction closer to the electronic component or in the direction away from the electronic component with respect to the another core.

3. The semiconductor device according to claim 1, wherein
the plurality of connection members are, in a plan view from the lamination direction, arrayed on a plurality of straight lines each of which extends along the two opposing side surfaces of the electronic component and that have different distances from a center of the electronic component, and
at connection members that are arrayed on the straight line that is closest to the electronic component or on the straight line that is disposed farthest from the electronic component among the plurality of connection members, the one core is arranged so as to be offset in the direction closer to the electronic component or in the direction away from the electronic component with respect to the another core.

4. The semiconductor device according to claim 3, wherein
the plurality of connection members are, in a plan view from the lamination direction, arrayed on the plurality of straight lines or on another plurality of straight lines that extend along another two opposing side surfaces of the electronic component, and
at connection members that are arrayed on the straight line or on the another straight line that is closest to the electronic component among the plurality of connection members, the one core is arranged so as to be offset in the direction closer to the electronic component or in the direction away from the electronic component with respect to the another core.

5. The semiconductor device according to claim 1, wherein, at all of the plurality of connection members, the one core is arranged so as to be offset in the direction closer to the electronic component or in the direction away from the electronic component with respect to the another core.

6. The semiconductor device according to claim 1, wherein
the first wiring substrate incudes a first pad that is connected to a corresponding connection member of the connection members that are arrayed in the innermost row or the outermost row with respect to the electronic component,
the second wiring substrate includes a second pad that is connected to the corresponding connection member of the connection members that are arrayed in the innermost row or the outermost row with respect to the electronic component, and
the second pad is arranged so as to be offset in the direction closer to the electronic component or in the direction away from the electronic component with respect to the first pad.

7. The semiconductor device according to claim 6, wherein
the first wiring substrate includes a first insulating layer that covers an upper surface of a base material of the first wiring substrate and that includes an opening portion that allows the first pad to be exposed,
the second wiring substrate includes a second insulating layer that covers a lower surface of a base material of the second wiring substrate and that includes an opening portion that allows the second pad to be exposed, and
the opening portion included in the second insulating layer is arranged so as to be offset in the direction closer to the electronic component or in the direction away from the electronic component with respect to the opening portion included in the first insulating layer.

8. The semiconductor device according to claim 1, wherein
each of the plurality of connection members is an integrated object that is formed by integrating a conductor film used for a first conductor ball that is formed by covering the one core by the conductor film and that is mounted on the first wiring substrate and a conductor film used for a second conductor ball that is formed by covering the another core by the conductor film and that is mounted on the second wiring substrate, and
an offset amount of the one core with respect to the another core is smaller than a diameter of the first conductor ball or the second conductor ball.

9. The semiconductor device according to claim 1, wherein, at connection members that are arrayed in at least the innermost row or the outermost row with respect to the electronic component among the plurality of connection members, the one core of the pair of cores that is disposed at a position closer to the second wiring substrate is arranged so as to be offset in the direction closer to a center of the electronic component or in the direction away from the center of the electronic component with respect to the another core of the pair of cores that is disposed at a position closer to the first wiring substrate.
